(19) United States
(12) Patent Application Publication
(10) Pub. No.: US 2024/0234496 A1
(43) Pub. Date: Jul. 11, 2024

(54) METHOD OF MANUFACTURING SILICON CARBIDE SEMICONDUCTOR DEVICE

(71) Applicant: FUJI ELECTRIC CO., LTD., Kawasaki-shi (JP)

(72) Inventors: Kensuke TAKENAKA, Tsukuba-city (JP); Shinsuke HARADA, Tsukuba-city (JP)

(73) Assignee: FUJI ELECTRIC CO., LTD., Kawasaki-sh (JP)

(21) Appl. No.: 18/399,996

(22) Filed: Dec. 29, 2023

(30) Foreign Application Priority Data
Jan. 6, 2023 (JP) 2023-001385

(51) Int. Cl. H01L 29/06; H01L 21/04; H01L 29/16; H01L 29/66; H01L 29/78

(52) U.S. Cl. CPC H01L 29/0634; H01L 21/046; H01L 29/1608; H01L 29/66068; H01L 29/7813

(57) ABSTRACT

A method of manufacturing a silicon carbide semiconductor device includes preparing a silicon carbide semiconductor substrate of a first conductivity type; forming a first semiconductor layer of a first conductivity type at a surface of the silicon carbide semiconductor substrate, the first semiconductor layer having a first surface and a second surface opposite to each other, the second surface facing the silicon carbide semiconductor substrate; implanting ions of an inert element into a region of a surface layer of the first semiconductor layer, thereby, inducing ion implantation damage to a crystal structure of the region in which a long tail occurs, the surface layer being at the first surface of the first semiconductor layer; and implanting a dopant of a second conductivity type into the surface layer of the first semiconductor layer where the crystal structure is damaged, thereby, forming column regions of the second conductivity type.

### CROSS REFERENCE TO RELATED APPLICATIONS

This application is based upon and claims the benefit of priority of the prior Japanese Patent Application No. 2023-001385, filed on Jan. 6, 2023, the entire contents of which are incorporated herein by reference.

### BACKGROUND OF THE INVENTION

### 1. Field of the Invention

Embodiments of the invention relate to a method of manufacturing a silicon carbide semiconductor device.

### 2. Description of the Related Art

In a common n-type-channel vertical metal oxide semiconductor field effect transistor (MOSFET), an n-type conduction layer (drift layer) is a semiconductor layer having the highest resistance among multiple semiconductor layers formed in a semiconductor substrate. Resistivity of the n-type drift layer significantly affects on-resistance of the vertical MOSFET overall. Reduction of the on-resistance of the vertical MOSFET may be realized by shortening the current path by reducing the thickness of the n-type drift layer.

Nonetheless, during an off-state, the vertical MOSFET further has a function of sustaining a breakdown voltage by the spreading of a depletion layer into the high-resistance n-type drift layer. Therefore, in an instance in which the n-type drift layer is reduced in thickness to lower the on-resistance, the spreading of the depletion layer during the off-state is shortened, whereby the critical field strength is easily reached by a low applied voltage and the breakdown voltage decreases. On the other hand, to increase the breakdown voltage of the vertical MOSFET, the thickness of the n-type drift layer has to be increased, whereby the on-resistance increases. A relationship such as this between the on-resistance and the breakdown voltage is called a tradeoff relationship and in general, it is difficult to improve both properties in a tradeoff relationship.

As for a structure of a semiconductor device that solves the problems described above, a super junction (SJ) structure is known. For example, MOSFETs having a super junction structure (hereinafter, SJ-MOSFETs) are commonly known.

A SJ-MOSFET has a parallel structure (hereinafter, referred to as “parallel pn region”) in which, in the n-type drift layer, p-type regions (p-type column regions) each extending in a direction orthogonal to a substrate main surface and having a relatively narrower width in a plane parallel to the substrate main surface, repeatedly alternate with n-type regions (portions of the n-type drift layer sandwiched between the p-type column regions, hereinafter, referred to as “n-type column regions) in a plane parallel to the substrate main surface. The n-type column regions configuring the parallel pn region are regions where the doping concentration is a relatively higher than that the n-type drift layer. In the parallel pn region, the doping concentrations contained in the p-type column regions and in the n-type column regions are substantially equal, whereby during the off-state, a pseudo non-doped layer may be created, enabling high breakdown voltage.

Further, according to a known technique, by forming a first polycrystalline film having a specific crystal plane parallel to the film surface and performing ion implantation to the first polycrystalline film from one direction, grains having a predetermined crystal orientation that is controlled three-dimensionally are left while other crystal grains are amorphous and the crystal grains having the predetermined crystal orientation that is controlled three-dimensionally are used as seeds to crystallize amorphous regions (for example, refer to Japanese Laid-Open Patent Publication No. 2010-123788).

Further, according to another known technique, oblique rotation ion-implantation of silicon (Si) is performed to a main surface of a substrate and the crystal structure of the silicon constituting the main surface of the substrate is destroyed, whereby the main surface of the substrate is put in a state that facilitates diffusion of oxygen (for example, refer to Japanese Laid-Open Patent Publication No. H05-160119).

### SUMMARY OF THE INVENTION

According to an embodiment of the present invention, a method of manufacturing a silicon carbide semiconductor device, includes: preparing a silicon carbide semiconductor substrate of a first conductivity type, the silicon carbide semiconductor substrate having a first surface and a second surface opposite to each other; forming a first semiconductor layer of the first conductivity type at the first surface of the silicon carbide semiconductor substrate, the first semiconductor layer having a first surface and a second surface opposite to each other, the second surface of the first semiconductor layer facing the first surface of the silicon carbide semiconductor substrate; inducing damage to a crystal structure of a target region of the first semiconductor layer, the target region being in a surface layer of the first semiconductor layer at the first surface thereof where a long tail is to potentially occur; and after the inducing damage to the crystal structure, ion-implanting a dopant of a second conductivity type into the surface layer of the first semiconductor layer where the crystal structure is damaged, thereby, forming a plurality of column regions of the second conductivity type in the first semiconductor layer.

Objects, features, and advantages of the present invention are specifically set forth in or will become apparent from the following detailed description of the invention when read in conjunction with the accompanying drawings.

### BRIEF DESCRIPTION OF THE DRAWINGS

FIG. 1 is a cross-sectional view depicting a structure of a silicon carbide SJ-MOSFET according to an embodiment.

FIG. 2 is a cross-sectional view of a state of the silicon carbide SJ-MOSFET according to the embodiment during manufacture.

FIG. 3 is a cross-sectional view of a state of the silicon carbide SJ-MOSFET according to the embodiment during manufacture.

FIG. 4 is a graph depicting average ranges of Al ions in Si and SiC.

FIG. 5 is a graph depicting results of simulation of an Al ion implantation profile and SIMS analysis data.

FIG. 6 is a cross-sectional view depicting ion implantation with high acceleration energy.

### DETAILED DESCRIPTION OF THE INVENTION

First, problems associated with the conventional techniques are discussed. In a SJ-MOSFET with a structure like that described above, the n-type drift layer is epitaxially grown, a p-type dopant is ion-implanted into the n-type drift layer, and the formation of p-type regions is repeatedly performed multiple times, whereby the parallel pn region is formed. Conventionally, epitaxial growth and an ion-implantation process of multiple stages for forming a box profile are repeatedly performed eight times (sessions) to form the parallel pn region, however, formation of the parallel pn region by a single session to reduce man-hours is under study.

In a case in which a SJ-MOSFET with a breakdown voltage of 1.2 kV is formed on a 4H—SiC substrate, an n-type buffer layer of 4.40 μm and the n-type drift layer of about 4.55 μm are epitaxially grown, a p-type dopant is ion-implanted into the n-type drift layer by acceleration energies of multiple stages so that a box profile is formed, a process of forming p-type regions of about 4.55 μm is performed once, whereby the parallel pn region is formed. Here, deep ion implantation into the epitaxially grown n-type drift layer is necessary.

Conventionally, in this deep ion implantation, based on results of simulation of ion implantation profiles in an amorphous state, aluminum (Al) ions (dopant) are implanted into a monocrystalline 4H—SiC film epitaxially grown (hereinafter, referred to as “epi film”) by a high acceleration energy.

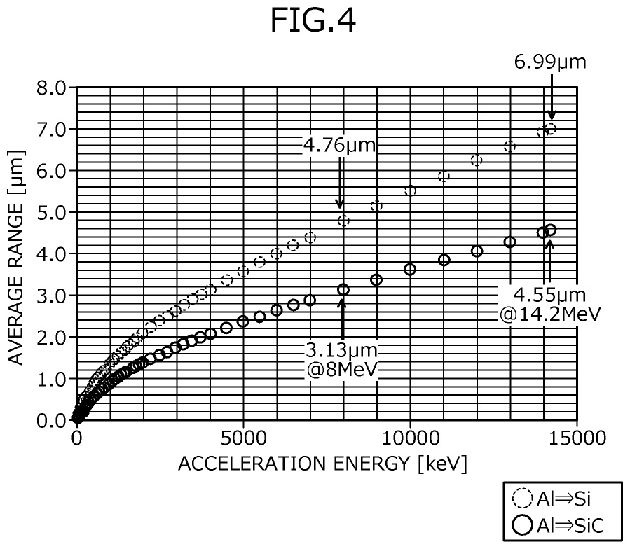

FIG. 4 is a graph depicting average ranges of Al ions in Si and SiC. In FIG. 4, a horizontal axis indicates acceleration energy in units of keV. A vertical axis indicates average ranges of Al ions in units of μm. The average ranges in FIG. 4 are simulation results. In FIG. 4, dotted-lined circles indicate average ranges when Al ions are implanted into Si while solid-lined circles indicate average ranges when Al ions are implanted into SiC. Simulation of the average ranges was performed assuming a density of the Si to be 2.3212 g/cm³ and a density of the SiC to be 3.21 g/cm³.

As depicted in FIG. 4, regarding SiC, the average range thereof is shorter than that of Si and acceleration energy up to about 14.2 MeV is necessary to form the p-type regions with a depth of 4.55 μm by one stage of box-profile ion implantation and Al ion implantation.

Nonetheless, under these conditions, when the p-type regions with the depth of 4.55 μm are formed, in the actual ion implantation profile, a long concentration distribution (hereinafter, called “long tail”) in the Al concentration profile occurs with the ion-implantation of Al ions into a deeper region and is thought to be due to a channeling effect on the ions scattered in the monocrystalline 4H—SiC epi film, the channeling effect being derived from the crystal structure of the monocrystalline 4H—SiC epi film. Due to the channeling effect, ions are implanted into deep regions, whereby characteristics of the semiconductor device degrade or variation from the design occurs.

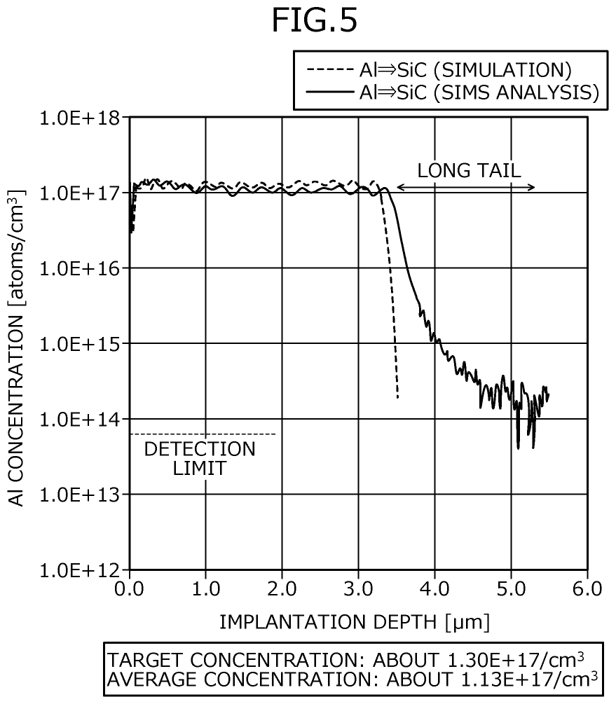

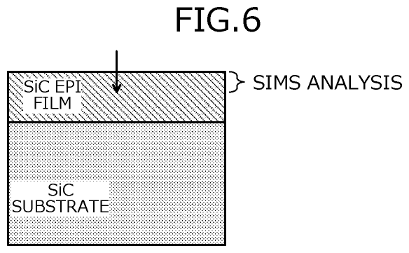

FIG. 5 is a graph depicting results of simulation of the Al ion implantation profile and SIMS analysis data. In FIG. 5, a horizontal axis indicates implantation depth of the Al ions in units of μm. A vertical axis indicates concentration of the Al ions in units of atoms/cm³. FIG. 6 is a cross-sectional view depicting ion implantation with high acceleration energy. In FIG. 5, a solid line indicates secondary ion mass spectrometry (SIMS) analysis data while a dotted line indicates simulation results. The SIMS analysis data in FIG. 5, as depicted in FIG. 6, are results of analysis of a region about 5.5 μm from the front surface after 15 stages of Al ion implantation with acceleration energies in a range of 60 keV to 8 MeV are performed to a SiC epi film that is about 10 μm, has an doping concentration of 3×10¹⁶/cm³, and is grown on the SiC substrate.

As depicted in FIG. 5, in the simulation, at a depth of 3.2 μm or more, the Al ion concentration abruptly decreases, forming a box profile, whereas in the SIMS analysis data, from a depth of 3.2 μm or more, a long tail occurs. Further, while a target concentration is about 1.30×10¹⁷/cm³, the average concentration is about 1.13×10¹⁷/cm³, and the average concentration of the Al ions decreases.

Concentration error in the SIMS analysis is about ±40% while measurement error in a depth direction is about ±5%.

One reason that the discrepancy between the simulation results and the SIMS analysis data is large in the depth direction is that the simulation does not take the crystal structure (amorphous) into consideration while in the actual ion implantation, a long tail is generated, which is thought to be due to the channeling effect derived by the crystal structure in the SiC epi film. Further, the higher is the acceleration energy (the deeper the implantation is intended), the deeper the long tail tends to be generated. Therefore, when ion implantation is performed to a deep region of 4.0 μm or more necessitating a high acceleration energy, a long tail is generated.

Embodiments of method of manufacturing a silicon carbide semiconductor device according to the present invention are described in detail with reference to the accompanying drawings. In the present description and accompanying drawings, layers and regions prefixed with n or p mean that majority carriers are electrons or holes. Additionally, + or − appended to n or p means that the doping concentration is higher or lower, respectively, than layers and regions without + or −. While cases where symbols such as n's and p's that include + or − are the same indicate that concentrations are close, the concentrations are not necessarily equal. In the description of the embodiments below and the accompanying drawings, main portions that are identical are given the same reference numerals and are not repeatedly described. Further, with consideration of variation in manufacturing, description indicating the same or equal may be within 5%.

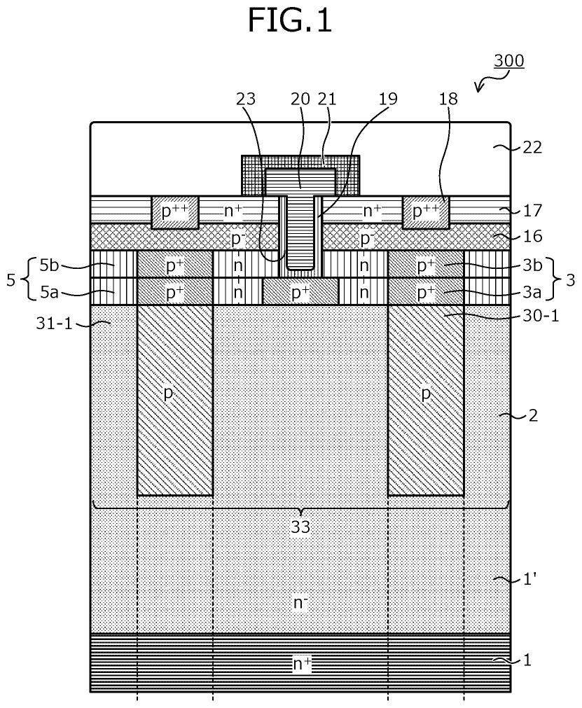

An SJ-MOSFET is described as an example of a semiconductor device according to the present invention. FIG. 1 is a cross-sectional view depicting a structure of the silicon carbide SJ-MOSFET according to the embodiment. A silicon carbide SJ-MOSFET 300 depicted in FIG. 1 is an SJ-MOSFET having a semiconductor base (silicon carbide base: semiconductor chip) containing silicon carbide (SiC) and a metal oxide semiconductor (MOS) gate in the semiconductor base, at a front surface (surface closest to a p⁻-type base region 16) of the semiconductor base. In FIG. 1, only two unit cells (functional units of a device) are depicted and depiction of other unit cells adjacent to these is omitted.

An n⁺-type silicon carbide substrate (silicon carbide semiconductor substrate of a first conductivity type) 1 is a monocrystalline silicon carbide substrate doped with, for example, nitrogen (N). An n⁻-type buffer layer 1′ and an n⁻-type drift layer (first semiconductor layer of a first conductivity type) 2 have lower doping concentrations than that of the n⁺-type silicon carbide substrate 1 and constitute, for example, a low-concentration n-type buffer layer doped with nitrogen, and an n-type drift layer. The doping concentration of the n⁻-type buffer layer 1′ is in a range of, for example, 5.0×10¹⁵/cm³ to 2.5×10¹⁶/cm³. The doping concentration of the n⁻-type drift layer 2 is, for example, in a range of 1.1×10¹⁶/cm³ to 5.0×10¹⁶/cm³.

Hereinafter, the n⁺-type semiconductor substrate 1, the n⁻-type buffer layer 1′, the n⁻-type drift layer 2, and the later-described p⁻-type base region 16 collectively are assumed as the semiconductor base. In the semiconductor base, at the front surface thereof, a MOS gate (metal-oxide film-semiconductor insulated gate) structure (device structure) is formed. Further, at a back surface of the semiconductor base, a drain electrode (not depicted) is provided.

In an active region of the silicon carbide SJ-MOSFET 300, a parallel pn region 33 is provided. In the parallel pn region 33, n-type column regions 31 and p-type column regions 30 are disposed repeatedly alternating with one another. The n-type column regions 31, as described hereinafter, are formed by one or more epitaxial growth processes and the p-type column regions 30, as described hereinafter, are formed by one or more stages of an ion implantation process having one or more stages. While the p-type column regions 30 constitute a semi-SJ structure provided from a surface of the n⁻-type drift layer 2 and not reaching a surface of the n⁺-type semiconductor substrate 1, the p-type column regions 30 may be a full-SJ structure reaching a vicinity of the surface of the n⁺-type semiconductor substrate 1. In a device plan view, shapes of the n-type column regions 31 and the p-type column regions 30 are, for example, stripe shapes. In a surface layer of the parallel pn region 33, at a first surface thereof (surface facing a first main surface of the silicon carbide semiconductor base) opposite to a second surface thereof facing the n⁺-type silicon carbide substrate 1, the p⁻-type base region (second semiconductor layer of a second conductivity type) 16 is provided.

Further, an n-type high-concentration region 5 maybe provided at a surface of the parallel pn region 33. In the n-type high-concentration region 5, a p⁺-type region 3 maybe selectively provided. The n-type high-concentration region 5 is a high-concentration n-type drift layer doped with, for example, nitrogen and has an doping concentration lower than that of the n⁺-type silicon carbide substrate 1 but higher than that of the n⁻-type drift layer 2. The n-type high-concentration region 5 is a so-called current spreading layer (CSL) that reduces carrier spreading resistance. The n-type high-concentration region 5, for example, is provided uniformly in a direction parallel to a base front surface (front surface of the semiconductor base).

Portions of the p⁺-type region 3 are provided at bottoms of trenches 23; a width of the p⁺-type region 3 is wider than a width of the trenches 23. The p⁺-type region 3 is doped with, for example, aluminum (Al). Further, portions of the p⁺-type region 3 are provided between the trenches 23; a surface thereof is in contact with the p-type base region 16 and a bottom surface thereof is in contact with the p-type column regions 30.

The p⁺-type region 3 is provided, whereby in a vicinity of the bottoms of the trenches 23, pn junctions between the p⁺-type region 3 and the n-type high-concentration region 5 maybe formed. The pn junctions between the p⁺-type region 3 and the n-type high-concentration region 5 are positioned deeper than are the trenches 23 and thus, electric field concentrates at a border between the p⁺-type region 3 and the n-type high-concentration region 5, enabling mitigation of electric field concentration at the bottoms of the trenches 23.

In the silicon carbide semiconductor base, at the first main surface (surface closest to the p⁻-type base region 16), a trench structure is formed. In particular, the trenches 23 penetrate through the p⁻-type base region 16, from a first surface thereof (first main surface of the silicon carbide semiconductor base) opposite to a second surface thereof facing the n⁺-type silicon carbide substrate 1 and reach the n-type high-concentration region 5 (in an instance in which the n-type high-concentration region 5 is omitted, the n-type column regions 31). Along inner walls of the trenches 23, a gate insulating film 19 is provided at the bottoms and sidewalls of the trenches 23; gate electrodes 20 are formed on the gate insulating film 19 in the trenches 23. The gate electrodes 20 are insulated from the n-type column regions 31 and the p⁻-type base region 16 by the gate insulating film 19. A portion of each of the gate electrodes 20 may protrude from an upper side (side facing a source electrode 22) of the trenches 23, in a direction to the source electrode 22.

In the p⁻-type base region 16, at a base first main surface side thereof, n⁺-type source regions (first semiconductor regions of the first conductivity type) 17 are selectively provided. The n⁺-type source regions 17 are in contact with the trenches 23. In the p⁻-type base region 16, p⁺⁺-type contact regions 18 maybe selectively provided. In this instance, the n⁺-type source regions 17 and the p⁺⁺-type contact regions 18 are in contact with one another. Further, in the embodiment, the p-type column regions 30 are provided directly beneath contact holes. In other words, the p-type column regions 30 are provided in regions between the n⁺-type silicon carbide substrate 1 and the n⁺-type source regions 17 and the p⁺⁺-type contact regions 18 that are in contact with the source electrode 22.

An interlayer insulating film 21 is provided in an entire area of a first main surface of silicon carbide semiconductor base and covers the gate electrodes 20 embedded in the trenches 23. The source electrode 22 is in contact with the n⁺-type source regions 17 and the p⁺⁺-type contact regions 18, via contact holes opened in the interlayer insulating film 21. The source electrode 22 is electrically insulated from the gate electrodes 20 by the interlayer insulating film 21. On the source electrode 22, a source pad (not depicted) is provided. Between the source electrode 22 and the interlayer insulating film 21, for example, a barrier metal (not depicted) that prevents diffusion of metal ions from the source electrode 22 to the gate electrodes 20 maybe provided.

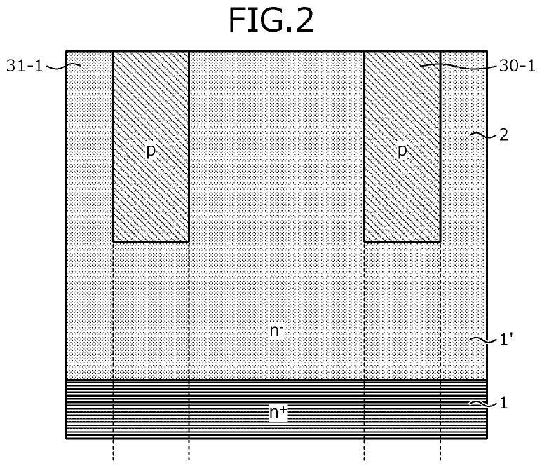

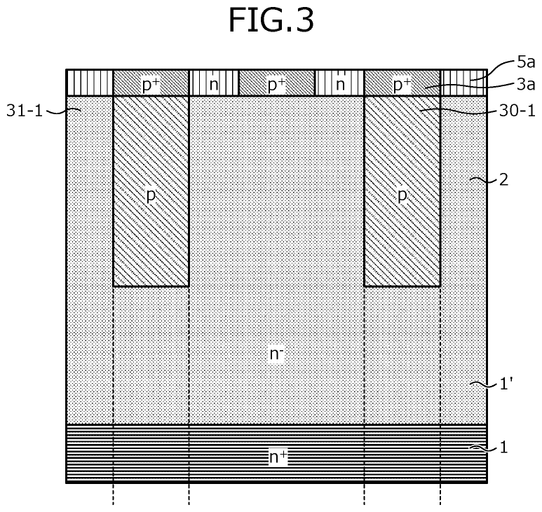

Next, a method of manufacturing the silicon carbide semiconductor device according to the embodiment is described. FIGS. 2 and 3 are cross-sectional views of states of the silicon carbide SJ-MOSFET according to the embodiment during manufacture. In the embodiment, the method of manufacturing is described taking a silicon carbide SJ-MOSFET having a trench structure of a 1.2 kV breakdown voltage class as an example.

First, the n⁺-type silicon carbide substrate 1 containing an n-type silicon carbide is prepared. Subsequently, on the first main surface of the n⁺-type silicon carbide substrate 1, the n⁻-type buffer layer 1′ containing silicon carbide and having a thickness of 4.40 μm is epitaxially grown while an n-type dopant, for example, nitrogen atoms, is doped to have an doping concentration of about 1.8×10¹⁶/cm³. Next, at a front surface of the n⁻-type buffer layer 1′, the n⁻-type drift layer 2 constituting first n-type column regions 31-1 containing silicon carbide and having an doping concentration higher than that of the n⁻-type buffer layer 1′ is epitaxially grown while, for example, nitrogen atoms are doped to have an doping concentration of about 3.0×10¹⁶/cm³.

Next, on the surface of the n⁻-type drift layer 2, an ion implantation mask having predetermined openings is formed by a photolithographic technique using, for example, a polysilicon film with a thickness of 10.0 μm or an SiO₂ film with a thickness of 10.0 μm. Next, the crystal structure of a region (target region) where the long tail of the surface layer of the n⁻-type drift layer 2 occurs is destroyed to an extent that the crystal structure does not become amorphous, by ion implantation damage subjected thereto. Here, preferably, the crystal structure of the monocrystalline 4H—SiC in each entire region where first p-type column regions 30-1 are formed may be destroyed. For example, preferably, in an instance in which the first p-type column regions 30-1 are formed having a thickness of about 4.55 μm, the crystal structure of the monocrystalline 4H—SiC may be destroyed to an extent that no amorphous state occurs up to a depth of about 4.55 μm. Here, destroying the crystal structure by subjecting the crystal structure to ion implantation damage to an extent that no amorphous state occurs means inflicting damage to an extent that the 4H—SiC crystal structure of crystal subject to damage by later-described activation annealing may be recovered. The extent of damage of the crystal structure by ion implantation may be adjusted mainly by the acceleration energy of the ion implantation.

Destruction of the crystal structure of the monocrystalline 4H—SiC may be realized by, for example, ion-implanting ions of an inert element such as Ar. In an instance of Ne, the acceleration energy is assumed to be 11.55 MeV; in an instance of Ar, the acceleration energy is assumed to be 18.35 MeV; in an instance of Kr, the acceleration energy is assumed to be 22.3 MeV; and in an instance of Xe, the acceleration energy is assumed to be 28.8 MeV, whereby the average range is 4.55 μm. To suppress the occurrence of the long tail in the SiC, it is desirable to inflict damage to a depth of about 5.05 μm and in an instance of Ne, the acceleration energy is assumed to be 13.16 MeV; in an instance of Ar, the acceleration energy is assumed to be 21.5 MeV; in an instance of Kr, the acceleration energy is assumed to be 26.7 MeV; and in an instance of Xe, the acceleration energy is assumed to be 34.1 MeV, whereby the average range is 5.05 μm. Next, a p-type dopant such as aluminum is ion-implanted in the openings of the SiO₂ film (hereinafter, referred to as “oxide film”), thereby forming the first p-type column regions 30-1. Next, the ion implantation mask is removed. The state up to here is depicted in FIG. 2,

As described, in the embodiment, before ion-implanting the p-type dopant in a region where the long tail of the n⁻-type drift layer 2 occurs, the crystal structure of the monocrystalline 4H—SiC thereof is destroyed first by first implanting ions of an inert element and inflicting ion implantation damage therein. As a result, during the ion implantation of the p-type dopant, penetration of the ions is inhibited, channeling does not easily occur, and the occurrence of the long tail in the p-type dopant concentration profile derived by the crystal structure may be prevented. Therefore, the doping concentration distribution in the depth direction is resolved and a region closely resembling the simulation may be manufactured.

Further, in the silicon carbide semiconductor substrate, an off-angle is provided and there is variation of the off-angle in each silicon carbide semiconductor substrate. Due to this variation, the angle of incidence of the ions in the ion-implantation of the p-type dopant differs, whereby variation in the size of the long tail occurs. In the embodiment, the crystal structure of the monocrystalline 4H—SiC is destroyed by implanting ions of an inert element before the p-type dopant is ion-implanted and thus, when the p-type dopant is ion-implanted, variation in the size of the long tail due to variation of the off-angle may be suppressed.

Here, while one session of the processes from ion implantation to epitaxial growth is assumed to be performed, in an instance of a SJ-MOSFET with an even higher breakdown voltage, the number of sessions is dependent on the thickness of the parallel pn region 33, the acceleration energy of the ion implantation, etc. and may be any number of sessions.

Next, on the first n-type column regions 31-1 and the first p-type column regions 30-1, a lower n-type high-concentration region 5a containing silicon carbide may be epitaxially grown while an n-type dopant, for example, nitrogen atoms (N), is doped.

Next, on the surface of the lower n-type high-concentration region 5a, a non-depicted mask having predetermined openings is formed by a photolithographic technique using, for example, an oxide film. Subsequently, a p-type dopant, for example, aluminum atoms (Al), is ion-implanted by an ion implantation method using the oxide film as a mask. As a result, lower p⁺-type regions 3a are formed in the lower n-type high-concentration region 5a. The state up to here is depicted in FIG. 3. Next, the mask used during the ion implantation for forming the lower p⁺-type regions 3a is removed. The lower n-type high-concentration region 5a and the lower p⁺-type regions 3a may be formed by repeatedly performing multiple sessions of epitaxial growth and ion implantation.

Next, on the surface of the lower n-type high-concentration region 5a, an upper n-type high-concentration region 5b containing silicon carbide may be epitaxially grown while an n-type dopant, for example, nitrogen atoms (N), is doped.

Next, on the surface of the upper n-type high-concentration region 5b, a non-depicted mask having predetermined openings is formed by a photolithographic technique using, for example, an oxide film. Subsequently, a p-type dopant, for example, aluminum atoms (Al), is ion-implanted by an ion implantation method using the oxide film as a mask. As a result, upper p⁺-type regions 3b are formed in the upper n-type high-concentration region 5b. The upper p⁺-type regions 3b may be formed so as to be between the trenches 23. Next, the mask used during the ion implantation for forming the upper p⁺-type regions 3b is removed. The upper n-type high-concentration region 5b and the upper p⁺-type regions 3b may be formed by repeatedly performing multiple sessions of epitaxial growth and ion implantation. The lower n-type high-concentration region 5a and the upper n-type high-concentration region 5b together constitute the n-type high-concentration region 5 while the lower p⁺-type regions 3a and the upper p⁺-type regions 3b together constitute the p⁺-type region 3.

Next, on the surfaces of the n-type high-concentration region 5 and the p⁺-type region 3 (in an instance in which the n-type high-concentration region 5 and the p⁺-type region 3 are omitted, on the surfaces of the n-type column regions 31 and the p-type column regions 30), the p⁻-type base region 16 doped with a p-type dopant such as aluminum is formed. Next, on the surface of the p⁻-type base region 16, an ion implantation mask having predetermined openings is formed by photolithography using, for example, an oxide film. An n-type dopant such as phosphorus (P) is ion-implanted in the openings, thereby, forming the n⁺-type source regions 17 in portions of the p⁻-type base region 16, at the surface thereof. Next, the ion implantation mask used to form the n⁺-type source regions 17 is removed and an ion implantation mask having predetermined openings may be formed by a same method, a p-type dopant such as aluminum may be ion-implanted in portions of the p⁻-type base region 16, at the surface thereof, whereby, the p⁺⁺-type contact regions 18 maybe provided. The p⁺⁺-type contact regions 18 have an doping concentration that is set to be higher than an doping concentration of the p⁻-type base region 16.

Next, a heat treatment (annealing) is performed under an inert gas atmosphere, thereby, implementing an activation treatment of the first p-type column regions 30-1, the first n-type column regions 31-1, the n-type high-concentration region 5, the p⁺-type region 3, the n⁺-type source regions 17, and the p⁺⁺-type contact regions 18. As described, ion-implanted regions may be collectively activated by a single session of the heat treatment or may be activated by performing the heat treatment each time ion implantation is performed. By this annealing, the region of the surface layer of the n⁻-type drift layer 2 where the long tail occurs recovers from the described ion implantation damage induced thereto, and the 4H—SiC crystal structure is recovered.

Next, on the surface of the p⁻-type base region 16, a trench formation mask having predetermined openings is formed by photolithography using, for example, an oxide film. Next, the trenches 23, which penetrate through the p⁻-type base region 16 and reach the n-type high-concentration region 5 (in an instance in which the n-type high-concentration region 5 are omitted, the n-type column regions 31), are formed by dry etching. Next, the trench formation mask is removed.

Next, along the surfaces of the n⁺-type source regions 17 and the p⁺⁺-type contact regions 18 and the bottoms and sidewalls of the trenches 23, the gate insulating film 19 is formed. The gate insulating film 19 maybe formed by thermal oxidation by a heat treatment of a temperature of about 1000 degrees C. under an oxygen atmosphere. Further, the gate insulating film 19 maybe formed by a deposition method by a chemical reaction such as that for a high temperature oxide (HTO).

Next, on the gate insulating film 19, a polycrystalline silicon layer doped with, for example, phosphorus atoms is formed. The polycrystalline silicon layer may be embedded in the trenches 23. The polycrystalline silicon layer is patterned by photolithography and portions thereof are left in the trenches 23, thereby, forming the gate electrodes 20. A portion of each of the gate electrodes 20 may protrude externally from the trenches 23.

Next, for example, a phosphate glass having a thickness of about 1 μm is deposited so as to cover the gate insulating film 19 and the gate electrodes 20, whereby the interlayer insulating film 21 is formed. Next, the barrier metal (not depicted) containing titanium (Ti) or titanium nitride (TiN) may be formed so as to cover the interlayer insulating film 21. The interlayer insulating film 21 and the gate insulating film 19 are patterned by photolithography, thereby, forming contact holes that expose the n⁺-type source regions 17 and the p⁺⁺-type contact regions 18. Thereafter, a heat treatment (reflow) is performed and the interlayer insulating film 21 is planarized.

Next, in the contact holes and on the interlayer insulating film 21, a conductive film containing, for example, nickel (Ni) and constituting the source electrode 22 is formed. The conductive film is patterned by photolithography and only the source electrode 22 is left in the contact holes.

Next, a back electrode (not depicted) containing, for example, nickel is provided on the second main surface of the n⁺-type semiconductor substrate 1. Thereafter, a heat treatment is performed under an inert gas atmosphere of about 1000 degrees C., whereby the source electrode 22 and the back electrode (not depicted) that form ohmic junctions with the n⁺-type source regions 17, the p⁺⁺-type contact regions 18, and the n⁺-type semiconductor substrate 1 are formed.

Next, on the first main surface of the n⁺-type semiconductor substrate 1, an aluminum film having a thickness of about 5 μm is deposited by a sputtering method, the aluminum is removed by photolithography so that the source electrode 22 and the interlayer insulating film 21 are covered, whereby the source pad (not depicted) is formed.

Next, at the surface of the back electrode, for example, titanium (Ti), nickel, and gold (Au) are sequentially deposited, whereby a drain electrode pad (not depicted) is formed. Thus, the silicon carbide semiconductor device depicted in FIG. 1 is completed.

As described, according to the embodiment, before the first p-type column regions are formed by ion implantation of a p-type dopant, ions of an inert element are ion-implanted and ion implantation damage is induced to the monocrystalline 4H—SiC epi film, whereby the crystal structure of the monocrystalline 4H—SiC of the regions in which the p-type dopant is to be ion-implanted is first destroyed. As a result, internal penetration of the ions of the implanted p-type dopant is inhibited, channeling does not easily occur, and the occurrence of the long tail in the p-type dopant concentration profile derived by the crystal structure may be prevented. Further effects are achieved in that the lifetime of the drift layer is shortened by increasing the ion implantation damage and it becomes possible to enhance tolerance against conduction degradation of the SJ-MOSFET and to reduce reverse recovery loss during switching due to reduction of the amount of stored charge.

Further, in the embodiment, while the first p-type column regions are described as an example, the present invention is applicable in an instance in which a region of a depth of 1.0 μm or more is formed by ion implantation. The present invention is further applicable to a silicon carbide semiconductor device other than a silicon carbide SJ-MOSFET.

In the foregoing, while the present invention is described taking, as an example, an instance in which the MOS gate structure is configured on the first main surface of the silicon carbide substrate that contains silicon carbide, without limitation hereto, the type (for example, gallium nitride (GaN) or the like) of the wide bandgap semiconductor, orientation of the substrate main surface, etc. may be variously changed. Further, in the present invention, while the first conductivity type is assumed to be an n-type and the second conductivity type is assumed to be a p-type in the embodiments, the present invention is similarly implemented when the first conductivity type is a p-type and the second conductivity type is an n-type. Further, in the present invention, while an example of a structure in which the trenches are parallel to a longitudinal direction of the p-type column regions and the n-type column regions is described, similar effects are obtained for a structure in which the trenches are orthogonal to the longitudinal direction of the p-type column regions and the n-type column regions.

As described, the semiconductor device and the method of manufacturing a semiconductor device according to the present invention are useful for high-voltage semiconductor devices used in power converting equipment, power source devices of various types of industrial machines, and the like.

According to the present invention described above, before the p-type column regions are formed by ion implantation of a p-type dopant, ions of an inert element are ion-implanted and ion implantation damage is induced to the monocrystalline 4H—SiC epi film, whereby the crystal structure of the monocrystalline 4H—SiC of the region to be ion-implanted is damaged to an extent of not being destroyed. As a result, internal penetration of the ions of the implanted p-type dopant is inhibited, channeling does not easily occur, and the occurrence of the long tail in the p-type dopant concentration profile derived by the crystal structure may be prevented.

According to the method of manufacturing the silicon carbide semiconductor device of the present invention, an effect is achieved in that the occurrence of the long tail in the p-type dopant concentration profile is prevented, whereby the doping concentration distribution in the depth direction is resolved and concurrently with the manufacture of a region closely resembling that simulated, the lifetime of the drift layer is shortened by increasing the ion implantation damage and it becomes possible to enhance tolerance against conduction degradation of the SJ-MOSFET and to reduce reverse recovery loss during switching due to reduction of the amount of stored charge.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A method of manufacturing a silicon carbide semiconductor device, the method comprising:
preparing a silicon carbide semiconductor substrate of a first conductivity type, the silicon carbide semiconductor substrate having a first surface and a second surface opposite to each other;
forming a first semiconductor layer of the first conductivity type at the first surface of the silicon carbide semiconductor substrate, the first semiconductor layer having a first surface and a second surface opposite to each other, the second surface of the first semiconductor layer facing the first surface of the silicon carbide semiconductor substrate;
inducing damage to a crystal structure of a target region of the first semiconductor layer, the target region being in a surface layer of the first semiconductor layer at the first surface thereof where a long tail is to potentially occur; and
after the inducing damage to the crystal structure, ion-implanting a dopant of a second conductivity type into the surface layer of the first semiconductor layer where the crystal structure is damaged, thereby, forming a plurality of column regions of the second conductivity type in the first semiconductor layer.

2. The method according to claim 1, wherein
the inducing damage to the crystal structure includes implanting ions of neon, argon, krypton, or xenon into the target region in the surface layer.

3. The method according to claim 1, wherein
the target region has an extent where a 4H—SiC crystal structure therein is recoverable by an activation annealing treatment for the dopant ions implanted.

4. The method according to claim 1, wherein
each of the plurality of column regions has a thickness of 1.0 μm or more.

5. A method of manufacturing a silicon carbide semiconductor device, the method comprising:
preparing a silicon carbide semiconductor substrate of a first conductivity type, the silicon carbide semiconductor substrate having a first surface and a second surface opposite to each other;
forming a semiconductor layer with a parallel pn region on the first surface of the silicon carbide semiconductor substrate, including
forming a first semiconductor layer of the first conductivity type at the first surface of the silicon carbide semiconductor substrate, the first semiconductor layer having a first surface and a second surface opposite to each other, the second surface of the first semiconductor layer facing the first surface of the silicon carbide semiconductor substrate; and
forming in the first semiconductor layer, at the first surface thereof, a parallel pn region in which a plurality of first column regions of the first conductivity type and a plurality of second column regions of a second conductivity type are disposed repeatedly alternating with one another in a plane parallel to the first surface of the first semiconductor layer, the parallel pn region having a first surface and a second surface opposite to each other, the second surface of the parallel pn region facing the second surface of the first semiconductor layer;
forming a second semiconductor layer of the second conductivity type at the first surface of the parallel pn region;
selectively forming a first semiconductor region of the first conductivity type in the second semiconductor layer, the first semiconductor region having an doping concentration higher than an doping concentration of the first semiconductor layer;
forming a trench that penetrates through the first semiconductor region and the second semiconductor layer and reaches the parallel pn region;
forming a gate electrode in the trench via a gate insulating film; and
forming a first electrode in contact with the first semiconductor region and the second semiconductor layer, wherein
the forming the semiconductor layer with the parallel pn region includes
forming the first semiconductor layer of the first conductivity type by epitaxial growth,
inducing damage to a crystal structure of a target region in the first semiconductor layer, the target region being in a surface layer of the first semiconductor layer at the first surface thereof where a long tail is to potentially occur, and
after the inducing damage to the crystal structure, ion-implanting a dopant of a second conductivity type into the surface layer of the first semiconductor layer where the crystal structure is damaged, thereby, forming a plurality of second column regions of the second conductivity type in the first semiconductor layer, and
the forming the first semiconductor layer, the inducing damage and the ion-implanting are performed one or more times.

6. The method according to claim 5, wherein
the inducing damage to the crystal structure includes implanting ions of neon, argon, krypton, or xenon into the target region in the surface layer.

7. The method according to claim 5, wherein
the target region has an extent where a 4H—SiC crystal structure therein is recoverable by an activation annealing treatment for the dopant ions implanted.

8. The method according to claim 5, wherein
each of the plurality of column regions has a thickness of 1.0 μm or more.
